(19) United States
(12) Patent Application Publication
(10) Pub. No.: US 2019/0202136 A1
(43) Pub. Date: Jul. 4, 2019

(54) COMPONENT COUPLING VIA PLURALITY OF ADHESIVE ELEMENTS

(71) Applicant: Intel Corporation, Santa Clara, CA (US)

(72) Inventors: Taylor GAINES, Chandler, AZ (US); Mark SALTAS, Chandler, AZ (US); Amram EITAN, Scottsdale, AZ (US)

(21) Appl. No.: 15/859,318

(22) Filed: Dec. 29, 2017

(51) Int. Cl. B29C 65/48; B29C 65/02; C09J 9/02; C09J 163/00; C09J 175/04; C09J 5/06; H05K 1/18; H05K 3/32

(52) U.S. Cl. CPC B29C 65/4805; B29C 65/02; C09J 9/02; C09J 163/00; B29L 2031/3425; C09J 5/06; H05K 1/181; H05K 3/321; C09J 175/04

(57) ABSTRACT

Apparatuses, systems and methods associated with procedures and adhesive elements for affixing components together are disclosed herein. In embodiments, an assembly may include a first component and a second component coupled to the first component. The assembly may further include a plurality of adhesive elements located between the first component and the second component, wherein the plurality of adhesive elements couple the second component to the first component, and wherein each adhesive element of the plurality of adhesive elements is equidistance from adjacent adhesive elements of the plurality of adhesive elements. Other embodiments may be described and/or claimed.

### TECHNICAL FIELD

The present disclosure relates to the field of component assembly. More particularly, the present disclosure relates to procedures and adhesive elements for affixing components together.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

In legacy actively aligned microelectronic package coupling, a single adhesive element is positioned between a first component and a second component to be coupled together. The single adhesive element is sized to cover a majority of the area between the adjacent surfaces of the first component and the second component. The single adhesive element is then cured, usually in a curing system where external apparatuses to maintain the positions of the first component and the second component are absent. The single adhesive element may experience cure shrinkage during curing, which may result in one or both of the first component and the second component shifting during the curing. As components shrink and/or connection points between the components become less tolerant to shifting, the cure shrinkage may produce failures due to the shifting of the components.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an example assembly that implements a plurality of adhesive elements, according to various embodiments.

FIG. 2 illustrates an example assembly with reinforcement material, according to various embodiments.

FIG. 3 illustrates a cross-sectional view of an example assembly, according to various embodiments.

FIG. 4 illustrates an example procedure to produce an assembly with a plurality of adhesive elements, according to various embodiments.

FIG. 5 illustrates an example of a first component positioned adjacent to a second component for determination of the location where the first component is to be affixed to the second component, according to various embodiments.

FIG. 6 illustrates an example of a plurality of adhesive elements applied to the second component, according to various embodiments.

FIG. 7 illustrates an example of the plurality of adhesive elements applied to the first component, according to various embodiments.

FIG. 8 illustrates an example assembly with the first component positioned adjacent to the second component, according to various embodiments.

FIG. 9 illustrates an example assembly with a reinforcement material, according to various embodiments.

FIG. 10 illustrates an example computer-readable non-transitory storage medium that may be suitable for use to store instructions that cause an apparatus, in response to execution of the instructions by the apparatus, to practice selected aspects of the present disclosure, according to various embodiments.

FIG. 11 illustrates an example computer device that may employ the apparatuses and/or methods described herein, in accordance with various embodiments.

### DETAILED DESCRIPTION

Apparatuses and methods associated with adhesive elements for affixing components together are disclosed herein. In embodiments, an assembly may include a first component and a second component coupled to the first component. The assembly may further include a plurality of adhesive elements located between the first component and the second component, wherein the plurality of adhesive elements couple the second component to the first component, and wherein each adhesive element of the plurality of adhesive elements is equidistance from adjacent adhesive elements of the plurality of adhesive elements. Other embodiments may be described and/or claimed.

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

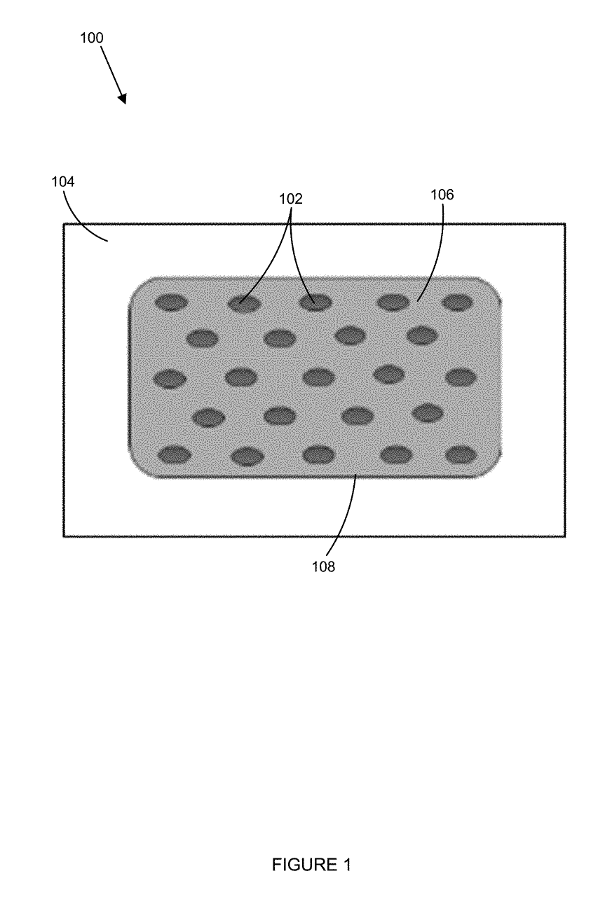

FIG. 1 illustrates an example assembly 100 that implements a plurality of adhesive elements 102, according to various embodiments. The assembly 100 may include a first component 104 and a second component 106 (illustrated transparently to show the plurality of adhesive elements 102). In some embodiments, assembly 100 may be a laser assembly, a lens assembly, a fiber optics assembly, a camera module assembly, a projector assembly, a microelectromechanical device, a magnet assembly, a photonic assembly, a server assembly, a client assembly, a sensor assembly, a drone assembly, a tablet assembly, a microelectronic package assembly, or some combination thereof. Accordingly, the first component 104 and the second component 106 may be associated with a laser assembly, a lens assembly, a fiber optics assembly, a camera module assembly, a projector assembly, a microelectromechanical device, a magnetic assembly, a photonic assembly, a server assembly, a client assembly, a sensor assembly, a drone assembly, a tablet assembly, a microelectronic package assembly, or some combination thereof. For example, one or both of the first component 104 and the second component 106 may be transparent (such as a lens). Further, in some embodiments, the first component 104 and the second component 106 may include contacts that are to be electrically coupled to each other. In some embodiments, the first component 104 may be a substrate and the second component 106 may be a die.

The assembly further may include the plurality of adhesive elements 102. The plurality of adhesive elements 102 may include at least two adhesive elements. The adhesive elements 102 may be located between the first component 104 and the second component 106.

The adhesive elements 102 may include any type of adhesive material, such as cyanoacrylates (which may include carbon, hydrogen, nitrogen, oxygen, or some combination thereof), acrylate (which may include carbon, hydrogen, nitrogen, oxygen, or some combination thereof), urethane-based adhesive (which may include carbon, hydrogen, nitrogen, oxygen, or some combination thereof), epoxy, silicone, or some combination thereof. In some embodiments, the adhesive elements 102 may further be thermally conductive, electrically conductive, or nonconductive. In these embodiments, the adhesive elements 102 may further include fillers, such as alumina (which may include aluminum, oxygen, or some combination thereof) fillers, silver fillers, silica (which may include silicon, oxygen, or some combination thereof) fillers, or some combination thereof. For example, the alumina fillers may provide thermal conductivity, the silver fillers may provide electrical conductivity, and the silica fillers may provide nonconductivity. The adhesive elements 102 may be rigid and may maintain a position of the second component 106 relative to the first component 104.

The adhesive elements 102 may extend for an entirety of the area between the first component 104 and the second component 106. In the illustrated embodiment, since the second component 106 is smaller than the first component 104, the adhesive elements 102 may extend for an entirety of a surface of the second component 106 located adjacent to the first component 104. Further, each of the adhesive element of the plurality of adhesive elements 102 may be located substantially (within 5% variance) equidistance from the closest, adjacent adhesive elements of the plurality of adhesive elements 102. In some embodiments, the adhesive elements of the plurality of adhesive elements 102 closest to the outer edge 108 of the second component 106 may be substantially (within 5% variance) equidistance from the outer edge 108. Further, in some embodiments, the distance between each of the adjacent adhesive elements of the plurality of adhesive elements 102 may be substantially (within 5% variance) equal to the distance from the adhesive elements of the plurality of adhesive elements 102 closest to the outer edge 108 of the second component to the outer edge 108.

The adhesive elements 102 may be arranged in a uniform pattern between the first component 104 and the second component 106. In the illustrated embodiment, the adhesive elements 102 are illustrated in a diamond pattern. However, it is to be understood that the adhesive elements 102 may be arranged in other patterns in other embodiments, including a rectangular pattern, a diagonal pattern, and/or an off-set pattern.

Each of the adhesive elements of the plurality of adhesive elements 102 may be substantially (may include minor variations due to production tolerances, adhesive curing shrinkage, and/or adhesive flow during application) the same shape. In the illustrated embodiment, each of the adhesive elements of the plurality of adhesive elements 102 are illustrated as oval shaped. However, it is to be understood that each of the adhesive elements of the plurality of adhesive elements 102 may be any other shape, including, but not limited to, circle shaped, rectangle shaped, hexagonal shaped, and/or octagonal shaped.

Further, each of the adhesive elements of the plurality of adhesive elements 102 may be substantially (within 5% variance) uniformly sized. The size of each of the adhesive elements of the plurality of adhesive elements 102 may be selected based on an amount of tolerance for shifting between the first component 104 and the second component 106 during a curing process of the plurality of adhesive elements 102. In particular, in embodiments where the amount of tolerance for shifting is small, the size of the plurality of adhesive elements 102 may be selected to be small to cause less curing shrinkage and/or shifting. Whereas, in embodiments where the amount of tolerance for shifting is larger, the size of the plurality of adhesive elements 102 may be selected to be larger, allowing for greater curing shrinkage and/or shifting.

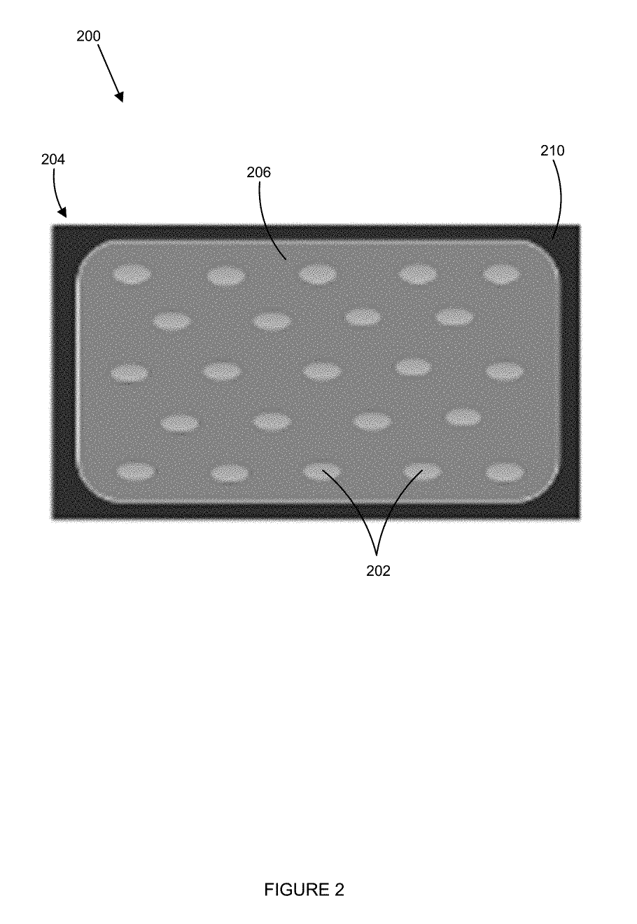

FIG. 2 illustrates an example assembly 200 with reinforcement material 210, according to various embodiments. The assembly 200 may include one or more of the features of the assembly 100 (FIG. 1). In particular, the assembly 200 may include a first component 204, a second component 206, and a plurality of adhesive elements 202, which may include one or more of the features of the first component 104 (FIG. 1), the second component 106 (FIG. 1), and the plurality of adhesive elements 102 (FIG. 1), respectively.

The assembly 200 may further include a reinforcement material 210 (illustrated by the shading). The reinforcement material 210 may be located between the first component 204 and the second component 206, and may extend outwards from the area between the first component 204 and the second component 206. In the illustrated embodiment, the reinforcement material 210 may extend for an entirety of a surface of the first component 204 directed toward the second component 206. It is to be understood that the reinforcement material 210 may extend for a portion of the surface of the first component 204 less than an entirety of the surface in other embodiments. Further, the reinforcement material 210 may encapsulate the plurality of adhesive elements 202. The encapsulation of the plurality of adhesive elements 202 by the reinforcement material 210 may protect the plurality of adhesive elements 202 from environmental factors and/or reduce wearing of the plurality of adhesive elements 202. In other embodiments, the reinforcement material 210 may be located between the first component 204 and the second component 206 and may not extend outwards from the area between the first component 204 and the second component 206.

The reinforcement material 210 may be a rigid material, which may further maintain a position of the second component 206 relative to the first component 204. In other embodiments, the reinforcement material 210 may not further maintain the position of the second component 206 relative to the first component 204.

The reinforcement material 210 may include a capillary underfill, a structural adhesive, a sealant, a thermal interface material, or some combination thereof. In some embodiments, the reinforcement material 210 may include any type of adhesive material, such as cyanoacrylates (which may include carbon, hydrogen, nitrogen, oxygen, or some combination thereof), acrylate (which may include carbon, hydrogen, nitrogen, oxygen, or some combination thereof), urethane-based adhesive (which may include carbon, hydrogen, nitrogen, oxygen, or some combination thereof), epoxy, silicone, or some combination thereof. In some embodiments, the reinforcement material 210 may further be thermally conductive, electrically conductive, or nonconductive. In these embodiments, the reinforcement material 210 may further include fillers, such as alumina (which may include aluminum, oxygen, or some combination thereof) fillers, silver fillers, silica (which may include silicon, oxygen, or some combination thereof) fillers, or some combination thereof. For example, the alumina fillers may provide thermal conductivity, the silver fillers may provide electrical conductivity, and the silica fillers may provide nonconductivity. In some embodiments, the reinforcement material 210 may be a same material as the plurality of elements 202.

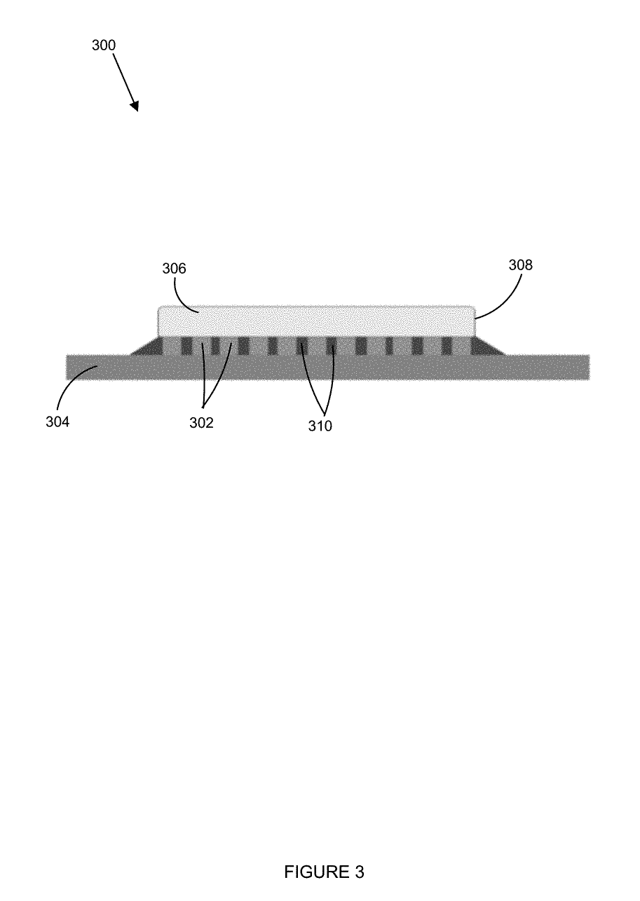

FIG. 3 illustrates a cross-sectional view of the example assembly 300, according to various embodiments. The assembly 300 may include one or more of the features of the assembly 200. For example, the assembly 300 may include a first component 304, a second component 306, a plurality of adhesive elements 302, and a reinforcement material 310, which may include one or more of the features of the first component 204 (FIG. 2), the second component 206 (FIG. 2), the plurality of adhesive elements 202 (FIG. 2), and the reinforcement material 210 (FIG. 2), respectively.

The plurality of adhesive elements 302 may be located between the first component 304 and the second component 306. Further, the plurality of adhesive elements 302 may be uniformly spaced between the first component 304 and the second component 306.

The reinforcement material 310 may be located between the first component 304 and the second component 306 and may extend outwards from the area between the first component 304 and the second component 306. In particular, a portion of the reinforcement material 310 may extend outwards from between the first component 304 and the second component 306 beyond an outer edge 308 of the second component 306 in one or more directions. In the illustrated embodiment, the reinforcement material 310 may extend for a portion of the first component 304 less than an entirety of a surface of the first component 304 directed toward the second component 306. The reinforcement material 310 may further encapsulate the plurality of adhesive elements 302.

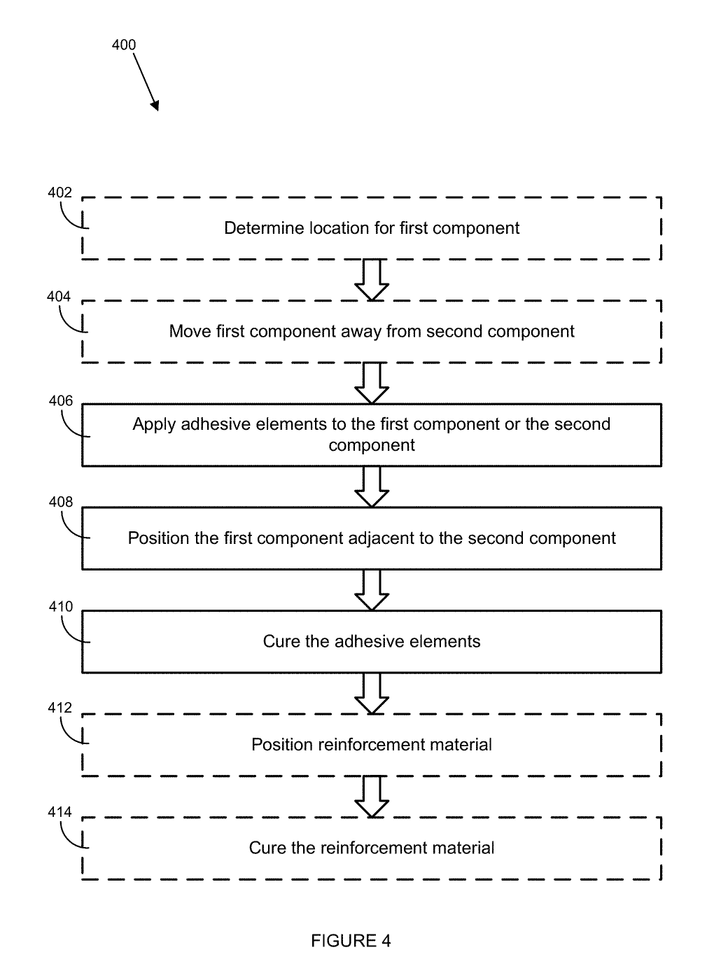

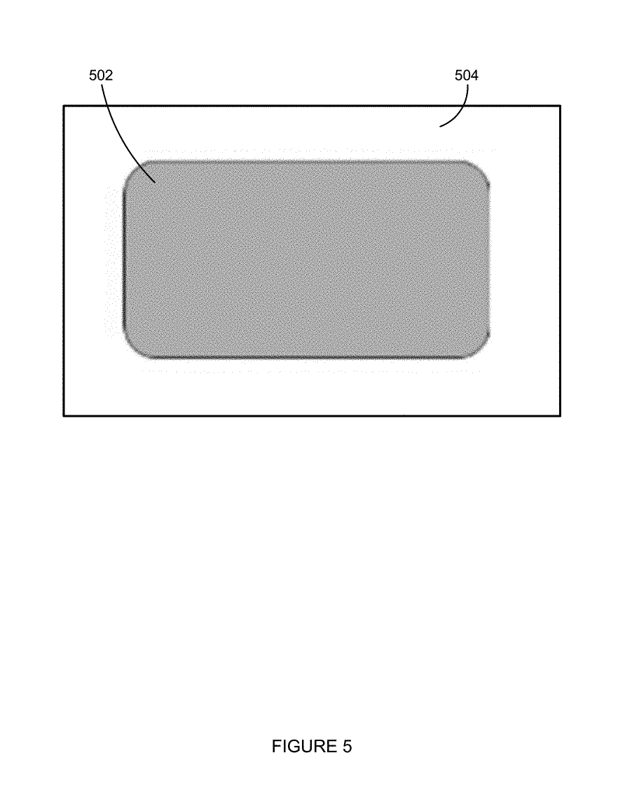

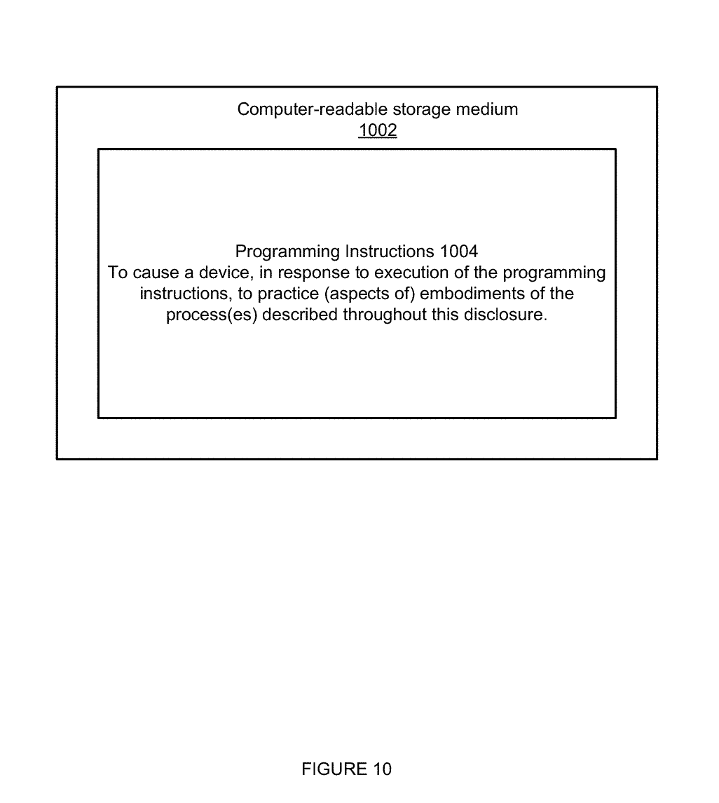

FIG. 4 illustrates an example procedure 400 to produce an assembly with a plurality of adhesive elements, according to various embodiments. In particular, the procedure 400 may produce an assembly, such as the assembly 100 (FIG. 1), the assembly 200 (FIG. 2), and/or the assembly 300 (FIG. 3). In some embodiments, the procedure 400 may be performed by an automated system that implements active alignment. In particular, a computer-readable storage medium (such as the computer-readable storage medium 1002 (FIG. 10)) may include instructions stored thereon that, when executed by the automated system, may cause the automated system to perform the procedure 400. FIGS. 5-9 may illustrate stages of the procedure 400, as referred to in the description of the procedure 400.

In some embodiments, the procedure 400 may initiate at stage 402. In stage 402, a location where a first component is to be affixed to a second component may be determined. In particular, the first component may be positioned adjacent to the second component to determine the location where the first component is to be affixed to the second component. For example, FIG. 5 illustrates an example of a first component 502 being positioned adjacent to a second component 504 for determination of the location where the first component 502 is to be affixed to the second component 504, in accordance with stage 402. The first component 502 and the second component 504 may include one or more of the features of the first component 104 (FIG. 1) and the second component 106 (FIG. 1), respectively.

In embodiments where the procedure 400 is performed by the automated system, a support of the automated system may position the first component adjacent to the second component and the support may provide feedback to the automated system to determine the location where the first component is to be affixed to the second component. The feedback may include a relationship between the first component and a feature of the second component, a mark or indication on the second component, one or more edges of the second component, or some combination thereof. Once the automated system determines that the first component is positioned in a desired location based on the feedback, the automated system may store an indication of the location of the current position, wherein the automated system may utilize the indication to return the first component to the location.

In stage 404, the first component may be moved away from the second component. In embodiments where the procedure 400 is performed by the automated system, the support of the automated system may move the first component away from the second component. In some embodiments, stage 402 and stage 404 may be omitted from the procedure 400.

In stage 406, a plurality of adhesive elements may be applied to the first component or the second component. The adhesive elements may be applied to the first component or the second component in accordance with the description of the positions of the plurality of adhesive elements 102 (FIG. 1).

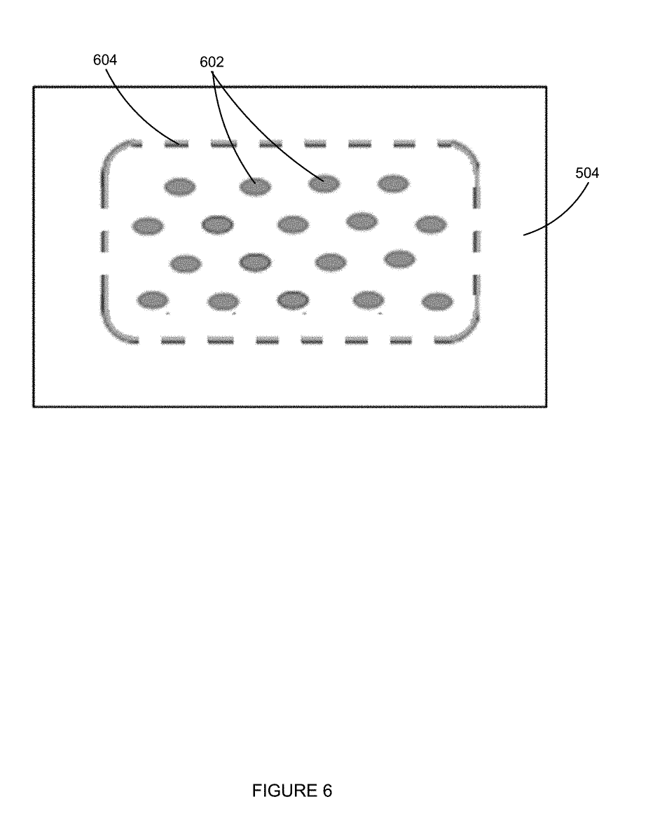

FIG. 6 illustrates an example of a plurality of adhesive elements 602 being applied to the second component 504, in accordance with stage 406. The plurality of adhesive elements 602 may include one or more of the features of the plurality of adhesive elements 102 (FIG. 1). In particular, the plurality of adhesive elements 602 may be applied to a surface of the second component 504 within an area 604 to which the first component 502 (FIG. 5) is to be affixed. The plurality of the adhesive elements 602 may extend across the entirety of the area 604, and each of the adhesive elements of the plurality of adhesive elements 602 may be applied equidistance from adjacent adhesive elements of the plurality of adhesive elements 602.

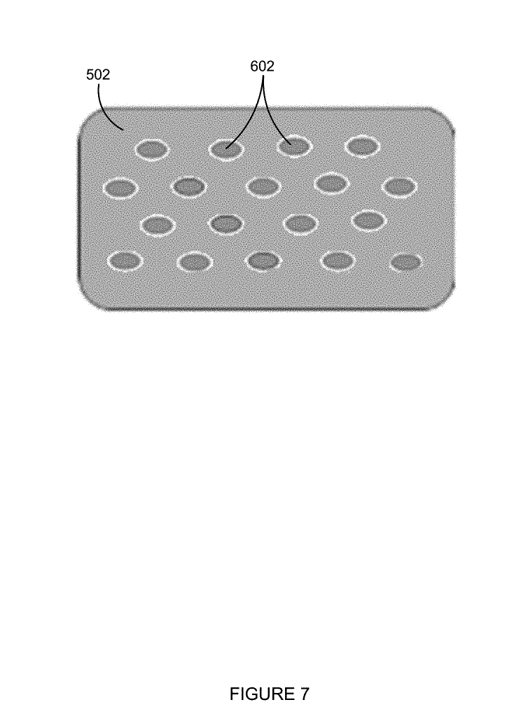

FIG. 7 illustrates an example of the plurality of adhesive elements 602 being applied to the first component 502, in accordance with stage 406. In particular, the plurality of adhesive elements 602 may be applied to a surface of the first component 502 to which the second component 504 (FIG. 5) is to be affixed. The plurality of adhesive elements 602 may extend across the entirety of the first component 502, and each of the adhesive elements of the plurality of adhesive elements 602 may be applied equidistance from adjacent adhesive elements of the plurality of adhesive elements 602.

In embodiments where the automated system performs the procedure 400, an applicator of the automated system may apply the plurality of adhesive elements to either the first component or the second component.

In stage 408, the first component may be positioned adjacent to the second component. In embodiments where stage 402 is included in procedure 400, the first component may be returned to the position determined in stage 402. The first component may be positioned with the plurality of adhesive elements located between the first component and the second component. The plurality of adhesive elements may contact a surface of the first component and the second component when the first component is positioned adjacent to the second component. In some embodiments, some pressure may be applied to the first component and/or the second component urging the first component and second component together, which may cause the plurality of adhesive elements to be slightly compressed between the first component and the second component.

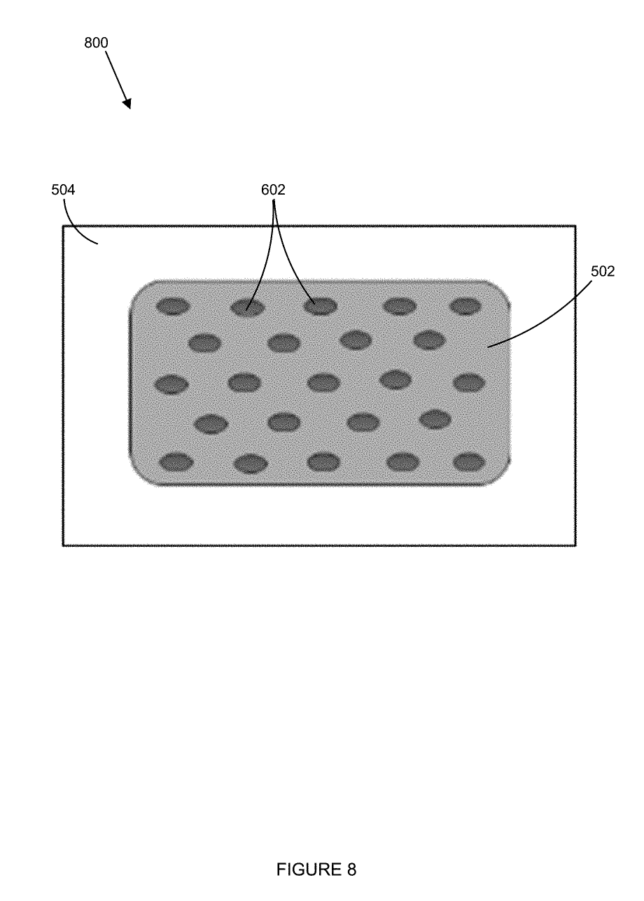

FIG. 8 illustrates an example assembly 800 with the first component 502 positioned adjacent to the second component 504, in accordance with stage 408. The plurality of adhesive elements 602 may be located between the first component 502 and the second component 504. Each of the adhesive elements of the plurality of adhesive elements 602 may contact both a surface of the first component 502 and a surface of the second component 504. The plurality of adhesive elements 602 may extend for an entirety of the area between the first component 502 and the second component 504, wherein each of the adhesive elements of the plurality of adhesive elements 602 may be located equidistance from adjacent adhesive elements of the plurality of adhesive elements 602.

In embodiments where the automated system performs the procedure 400, the support of the automated system may return the first component to the location determined in stage 402. In particular, the automated system may retrieve the stored indication of the location and utilize the indication of the location to cause the support of the automated system to return the first component to the location.

In stage 410, the plurality of adhesive elements may be cured. The plurality of adhesive elements may be cured by applying heat, light, chemicals, or some combination thereof to the plurality of the adhesive elements. The curing of the plurality of adhesive elements may cause the adhesive elements to become rigid. Further, the plurality of adhesive elements may affix the first component and the second component together after being cured.

During the curing, the plurality of adhesive elements may experience curing shrinkage. The amount of curing shrinkage may be a percentage of the size of each of the adhesive elements of the plurality of adhesive elements. The smaller the size of each of the adhesive elements, the smaller the amount of curing shrinkage. The reduced amount of the curing shrinkage may reduce the risk and/or amount of shifting of the first component and/or the second component during curing as compared to a large, single adhesive element that extends for a majority of the area between the first component and the second component. Further, the equidistance spacing between each of the adhesive elements of the plurality of adhesive elements and/or the extension of the plurality of adhesive elements for the entirety of the area between the first component and the second component may further reduce the risk and/or the amount of shifting of the first component and/or the second component. Accordingly, the reduced risk and/or amount of shifting of the first component and/or the second component may reduce the risk of failure of an assembly due to shifting of the first component and/or the second component from desired locations.

In embodiments where the procedure 400 is performed by an automated system, the automated system may apply the heat, light, chemicals, or some combination thereof, to the plurality of adhesive elements. In some embodiments, a support of the automated system may place the assembly (including the first component, the second component, and the plurality of adhesive elements) into an oven or other heat producing apparatus for curing the plurality of adhesive elements. The support of the automated system may be separate from the assembly during curing, which may allow the first component and/or the second component to shift during curing. The reduction in curing shrinkage of each of the adhesive elements of the plurality of adhesive elements may reduce the risk and/or amount of shifting of the first component and/or the second component during curing.

In stage 412, reinforcement material may be positioned between the first component and the second component. The reinforcement material may fill the area between the first component and the second component that is not occupied by the plurality of adhesive elements. The reinforcement material may be injected between the first component and the second component to fill the remainder of the area between the first component and the second component. In some embodiments, a portion of the reinforcement material may further extend outwards from between the first component and the second component.

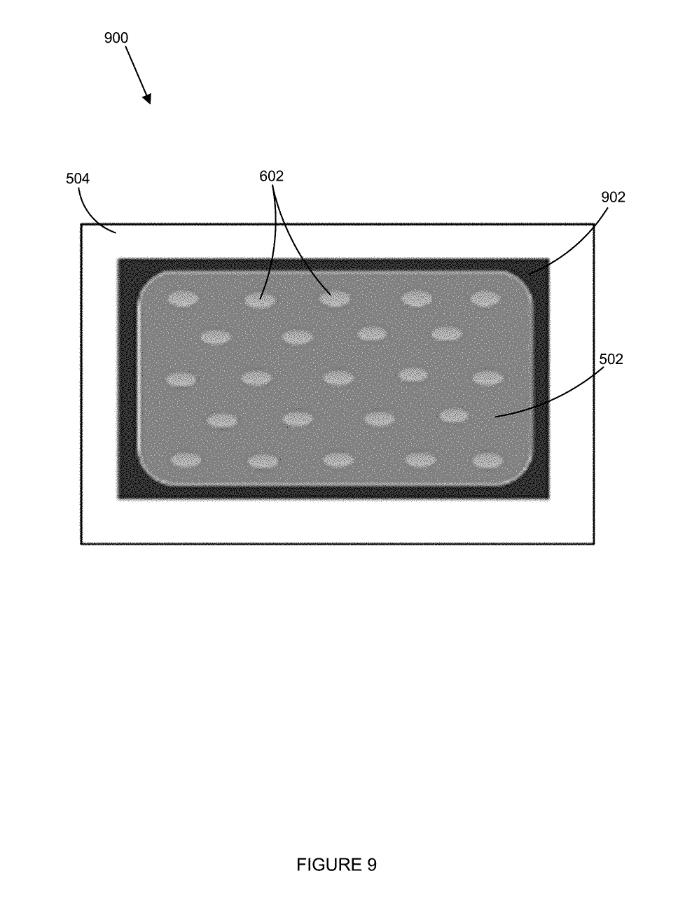

FIG. 9 illustrates an example assembly 900 with a reinforcement material 902, in accordance with stage 412. The reinforcement material 902 may include one or more of the features of the reinforcement material 210 (FIG. 2). The reinforcement material 902 may be located between the first component 502 and the second component 504. The reinforcement material 902 may encapsulate the plurality of adhesive elements 602 located between the first component 502 and the second component 504. Further, a portion of the reinforcement material 902 may extend outwards from between the first component 502 and the second component 504.

In embodiments where the automated system performs the procedure 400, an applicator of the automated system may inject the reinforcement material between the first component and the second component, in accordance with the description related to FIG. 9. The applicator may further apply the reinforcement material such that a portion of the reinforcement material extends outwards from between the first component and the second component. In some embodiments, the automated system may utilize a mold to form the reinforcement material in a desired shape.

In stage 414, the reinforcement material may be cured. The reinforcement material may be cured by applying heat, light, chemicals, or some combination thereof to the reinforcement material. In some embodiments, the reinforcement material may be cured by the same procedure by which the plurality of adhesive elements were cured. The curing of the reinforcement material may cause the reinforcement material to become rigid. The reinforcement material may further affix the first component and the second component together after being cured.

In embodiments where the procedure 400 is performed by an automated system, the automated system may apply the heat, light, chemicals, or some combination thereof, to the reinforcement material. In some embodiments, a support of the automated system may place the assembly (including the first component, the second component, the plurality of adhesive elements, and the reinforcement material) into an oven or other heat producing apparatus for curing the reinforcement material.

As will be appreciated by one skilled in the art, the present disclosure may be embodied as methods or computer program products. Accordingly, the present disclosure, in addition to being embodied in hardware as earlier described, may take the form of an entirely software embodiment (including firmware, resident software, micro-code, etc.) or an embodiment combining software and hardware aspects that may all generally be referred to as a “circuit,” “module” or “system.” Furthermore, the present disclosure may take the form of a computer program product embodied in any tangible or non-transitory medium of expression having computer-usable program code embodied in the medium. FIG. 10 illustrates an example computer-readable non-transitory storage medium that may be suitable for use to store instructions that cause an apparatus, in response to execution of the instructions by the apparatus, to practice selected aspects of the present disclosure. As shown, non-transitory computer-readable storage medium 1002 may include a number of programming instructions 1004. Programming instructions 1004 may be configured to enable a device, e.g., the automated system described in relation to FIG. 4, in response to execution of the programming instructions, to implement (aspects of) the procedure 400. In alternate embodiments, programming instructions 1004 may be disposed on multiple computer-readable non-transitory storage media 1002 instead. In still other embodiments, programming instructions 1004 may be disposed on computer-readable transitory storage media 1002, such as signals.

Any combination of one or more computer-usable or computer-readable medium(s) may be utilized. The computer-usable or computer-readable medium may be, for example, but not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer-usable program code may be transmitted using any appropriate medium, including but not limited to wireless, wireline, optical fiber cable, radio frequency (RF), etc.

Computer program code for carrying out operations of the present disclosure may be written in any combination of one or more programming languages, including an object oriented programming language such as Java, Smalltalk, C++or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The present disclosure is described with reference to flowchart illustrations and/or block diagrams of methods, apparatuses (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

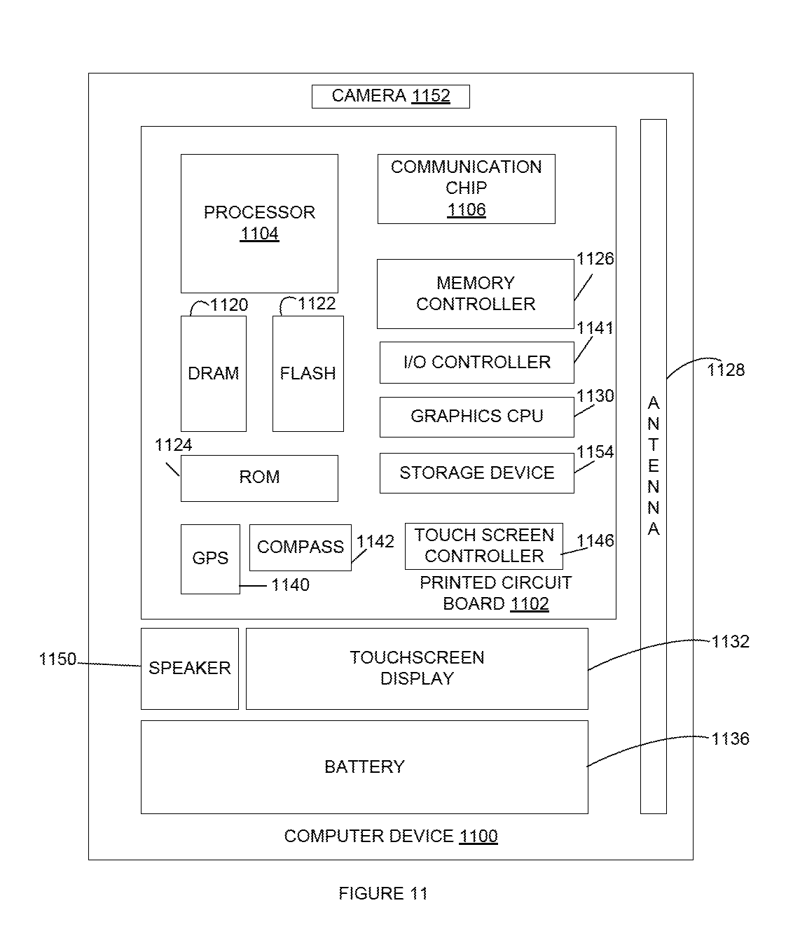

FIG. 11 illustrates an example computer device 1100 that may employ the apparatuses and/or methods described herein (e.g., the assembly 100, the adhesive elements 102, the assembly 200, the adhesive elements 202, the assembly 300, the adhesive elements 302, and/or the procedure 400), in accordance with various embodiments. As shown, computer device 1100 may include a number of components, such as one or more processor(s) 1104 (one shown) and at least one communication chip 1106. In various embodiments, the one or more processor(s) 1104 each may include one or more processor cores. In various embodiments, the at least one communication chip 1106 may be physically and electrically coupled to the one or more processor(s) 1104. In further implementations, the communication chip 1106 may be part of the one or more processor(s) 1104. In various embodiments, computer device 1100 may include printed circuit board (PCB) 1102. For these embodiments, the one or more processor(s) 1104 and communication chip 1106 may be disposed thereon. In alternate embodiments, the various components may be coupled without the employment of PCB 1102.

Depending on its applications, computer device 1100 may include other components that may or may not be physically and electrically coupled to the PCB 1102. These other components include, but are not limited to, memory controller 1126, volatile memory (e.g., dynamic random access memory (DRAM) 1120), non-volatile memory such as read only memory (ROM) 1124, flash memory 1122, storage device 1154 (e.g., a hard-disk drive (HDD)), an I/O controller 1141, a digital signal processor (not shown), a crypto processor (not shown), a graphics processor 1130, one or more antenna 1128, a display (not shown), a touch screen display 1132, a touch screen controller 1146, a battery 1136, an audio codec (not shown), a video codec (not shown), a global positioning system (GPS) device 1140, a compass 1142, an accelerometer (not shown), a gyroscope (not shown), a speaker 1150, a camera 1152, and a mass storage device (such as hard disk drive, a solid state drive, compact disk (CD), digital versatile disk (DVD)) (not shown), and so forth.

In some embodiments, the one or more processor(s) 1104, flash memory 1122, and/or storage device 1154 may include associated firmware (not shown) storing programming instructions configured to enable computer device 1100, in response to execution of the programming instructions by one or more processor(s) 1104, to practice all or selected aspects of the methods described herein. In various embodiments, these aspects may additionally or alternatively be implemented using hardware separate from the one or more processor(s) 1104, flash memory 1122, or storage device 1154.

In various embodiments, one or more components of the computer device 1100 may be coupled via the adhesive elements 102 (FIG. 1), the adhesive elements 202 (FIG. 2), and/or the adhesive elements 302 (FIG. 3). For example, the processor 1104 may be coupled to the PCB 1102 via the adhesive elements 102, the adhesive elements 202, and/or the adhesive elements 302.

The communication chips 1106 may enable wired and/or wireless communications for the transfer of data to and from the computer device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1106 may implement any of a number of wireless standards or protocols, including but not limited to IEEE 802.20, Long Term Evolution (LTE), LTE Advanced (LTE-A), General Packet Radio Service (GPRS), Evolution Data Optimized (Ev-DO), Evolved High Speed Packet Access (HSPA+), Evolved High Speed Downlink Packet Access (HSDPA+), Evolved High Speed Uplink Packet Access (HSUPA+), Global System for Mobile Communications (GSM), Enhanced Data rates for GSM Evolution (EDGE), Code Division Multiple Access (CDMA), Time Division Multiple Access (TDMA), Digital Enhanced Cordless Telecommunications (DECT), Worldwide Interoperability for Microwave Access (WiMAX), Bluetooth, derivatives thereof, as well as any other wireless protocols that are designated as 3G, 4G, 5G, and beyond. The computer device 1100 may include a plurality of communication chips 1106. For instance, a first communication chip 1106 may be dedicated to shorter range wireless communications such as Wi-Fi and Bluetooth, and a second communication chip 1106 may be dedicated to longer range wireless communications such as GPS, EDGE, GPRS, CDMA, WiMAX, LTE, Ev-DO, and others.

In various implementations, the computer device 1100 may be a laptop, a netbook, a notebook, an ultrabook, a smartphone, a computer tablet, a personal digital assistant (PDA), an ultra-mobile PC, a mobile phone, a desktop computer, a server, a printer, a scanner, a monitor, a set-top box, an entertainment control unit (e.g., a gaming console or automotive entertainment unit), a digital camera, an appliance, a portable music player, or a digital video recorder. In further implementations, the computer device 1100 may be any other electronic device that processes data.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

Example 1 may include an assembly, comprising a first component, a second component coupled to the first component, and a plurality of adhesive elements located between the first component and the second component, wherein the plurality of adhesive elements couple the second component to the first component.

Example 2 may include the assembly of example 1, wherein each adhesive element of the plurality of adhesive elements is equidistance from adjacent adhesive elements of the plurality of adhesive elements.

Example 3 may include the assembly of examples 1 or 2, wherein the plurality of adhesive elements extend for an entirety of a surface of the second component, wherein the surface is located adjacent to the first component.

Example 4 may include the assembly of examples 1 or 2, wherein the plurality of adhesive elements are uniformly sized.

Example 5 may include the assembly of examples 1 or 2, wherein the plurality of adhesive elements include carbon, hydrogen, nitrogen, oxygen, or silicon.

Example 6 may include the assembly of example 5, wherein the plurality of adhesive elements further include silver or aluminum.

Example 7 may include the assembly of examples 1 or 2, wherein the plurality of adhesive elements include an epoxy.

Example 8 may include the assembly of examples 1 or 2, wherein the plurality of adhesive elements are urethane-based.

Example 9 may include the assembly of examples 1 or 2, wherein the plurality of adhesive elements are electrically conductive.

Example 10 may include the assembly of examples 1 or 2, wherein the plurality of adhesive elements are positioned in a diamond-pattern.

Example 11 may include the assembly of examples 1 or 2, further comprising a reinforcement material located between the first component and the second component, wherein the reinforcement material encapsulates the plurality of adhesive elements.

Example 12 may include the assembly of example 11, wherein the reinforcement material includes a capillary underfill, a structural adhesive, a sealant, or thermal interface material.

Example 13 may include the assembly of example 11, wherein the reinforcement material includes a thermally conductive material.

Example 14 may include the assembly of examples 1 or 2, wherein the first component and the second component are associated with a laser assembly, a lens assembly, a fiber optics assembly, a camera module assembly, a projector assembly, a microelectromechanical device, a magnet assembly, or a photonic assembly.

Example 15 may include a method of coupling a first component and a second component, comprising applying a plurality of adhesive elements to the first component, positioning the first component adjacent to the second component with the plurality of adhesive elements located between the first component and the second component, wherein the plurality of adhesive elements contact both the first component and the second component, and curing the plurality of adhesive elements.

Example 16 may include the method of example 15, wherein each adhesive element of the plurality of adhesive elements is equidistance from adjacent adhesive elements of the plurality of adhesive elements.

Example 17 may include the method of examples 15 or 16, wherein one component of the first component or the second component is transparent, and wherein curing the plurality of adhesive elements includes directing light through the one component to cure the plurality of adhesive elements.

Example 18 may include the method of examples 15 or 16, wherein curing the plurality of adhesive elements includes applying heat to the plurality of adhesive elements.

Example 19 may include the method of examples 15 or 16, wherein positioning the first component on the second component includes moving, via a tool, the first component across the second component, receiving, from the tool, an indication that the first component is located in a location where the first component is to be coupled to the second component, moving, via the tool, the first component away from the second component, wherein the plurality of adhesive elements are applied while the first component is moved away from the second component, and moving, via the tool, the first component back to the location, wherein the plurality of adhesive elements are cured after the first component is moved back to the location.

Example 20 may include the method of examples 15 or 16, wherein the plurality of adhesive elements extend for an entirety of a surface of the first component.

Example 21 may include the method of examples 15 or 16, wherein the plurality of adhesive elements are a uniform size.

Example 22 may include the method of examples 15 or 16, wherein applying the plurality of adhesive elements includes applying the plurality of adhesive elements in a diamond-pattern.

Example 23 may include the method of examples 15 or 16, wherein the plurality of adhesive elements include carbon, hydrogen, nitrogen, oxygen, or silicon.

Example 24 may include the method of examples 15 or 16, wherein the plurality of adhesive elements further include silver and aluminum.

Example 25 may include the method of examples 15 or 16, wherein the plurality of adhesive elements include an epoxy.

Example 26 may include the method of examples 15 or 16, wherein the plurality of adhesive elements are urethane-based.

Example 27 may include the method of examples 15 or 16, wherein the plurality of adhesive elements are electrically conductive.

Example 28 may include the method of examples 15 or 16, further comprising positioning a reinforcement material between the first component and the second component, and curing the reinforcement material.

Example 29 may include the method of example 28, wherein the reinforcement material encapsulates the plurality of adhesive elements.

Example 30 may include the method of example 28, wherein the reinforcement material includes a capillary underfill, a structural adhesive, a sealant, or thermal interface material.

Example 31 may include the method of examples 15 or 16, wherein the method is performed by an automated system that implements active alignment.

Example 32 may include a computer device, comprising a printed circuit board (PCB), a component coupled to the PCB, and a plurality of adhesive elements located between the PCB and the component, wherein the plurality of adhesive elements couple the component to the PCB.

Example 33 may include the computer device of example 32, wherein each adhesive element of the plurality of adhesive elements is equidistance from adjacent adhesive elements of the plurality of adhesive elements.

Example 34 may include the computer device of examples 32 or 33, wherein the plurality of adhesive elements extend for an entirety of a surface of the component, wherein the surface is located adjacent to the PCB.

Example 35 may include the computer device of examples 32 or 33, wherein the plurality of adhesive elements are uniformly sized.

Example 36 may include the computer device of examples 32 or 33, wherein the plurality of adhesive elements include carbon, hydrogen, nitrogen, oxygen, or silicon.

Example 37 may include the computer device of example 36, wherein the plurality of adhesive elements further include silver or aluminum.

Example 38 may include the computer device of examples 32 or 33, wherein the plurality of adhesive elements include an epoxy.

Example 39 may include the computer device of examples 32 or 33, wherein the plurality of adhesive elements are urethane-based.

Example 40 may include the computer device of examples 32 or 33, wherein the plurality of adhesive elements are electrically conductive.

Example 41 may include the computer device of examples 32 or 33, wherein the plurality of adhesive elements are positioned in a diamond-pattern.

Example 42 may include the computer device of examples 32 or 33, further comprising a reinforcement material located between the PCB and the component, wherein the reinforcement material encapsulates the plurality of adhesive elements.

Example 43 may include the computer device of example 42, wherein the reinforcement material includes a capillary underfill, a structural adhesive, a sealant, or thermal interface material.

Example 44 may include the computer device of example 42, wherein the reinforcement material includes a thermally conductive material.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

What is claimed is:

1. An assembly, comprising:
a first component;
a second component coupled to the first component; and
a plurality of adhesive elements located between the first component and the second component, wherein the plurality of adhesive elements couple the second component to the first component.

2. The assembly of claim 1, wherein each adhesive element of the plurality of adhesive elements is equidistance from adjacent adhesive elements of the plurality of adhesive elements

3. The assembly of claim 1, wherein the plurality of adhesive elements extend for an entirety of a surface of the second component, wherein the surface is located adjacent to the first component.

4. The assembly of claim 1, wherein the plurality of adhesive elements are uniformly sized.

5. The assembly of claim 1, wherein the plurality of adhesive elements include carbon, hydrogen, nitrogen, oxygen, or silicon.

6. The assembly of claim 5, wherein the plurality of adhesive elements further include silver or aluminum.

7. The assembly of claim 1, wherein the plurality of adhesive elements include an epoxy.

8. The assembly of claim 1, wherein the plurality of adhesive elements are urethane-based.

9. The assembly of claim 1, wherein the plurality of adhesive elements are electrically conductive.

10. The assembly of claim 1, further comprising a reinforcement material located between the first component and the second component, wherein the reinforcement material encapsulates the plurality of adhesive elements.

11. A method of coupling a first component and a second component, comprising:
applying a plurality of adhesive elements to the first component;
positioning the first component adjacent to the second component with the plurality of adhesive elements located between the first component and the second component, wherein the plurality of adhesive elements contact both the first component and the second component; and
curing the plurality of adhesive elements.

12. The method of claim 11, wherein each adhesive element of the plurality of adhesive elements is equidistance from adjacent adhesive elements of the plurality of adhesive elements.

13. The method of claim 11, wherein one component of the first component or the second component is transparent, and wherein curing the plurality of adhesive elements includes directing light through the one component to cure the plurality of adhesive elements.

14. The method of claim 11, wherein curing the plurality of adhesive elements includes applying heat to the plurality of adhesive elements.

15. The method of claim 11, wherein positioning the first component on the second component includes:
moving, via a tool, the first component across the second component;
receiving, from the tool, an indication that the first component is located in a location where the first component is to be coupled to the second component;
moving, via the tool, the first component away from the second component, wherein the plurality of adhesive elements are applied while the first component is moved away from the second component; and
moving, via the tool, the first component back to the location, wherein the plurality of adhesive elements are cured after the first component is moved back to the location.

16. The method of claim 11, further comprising:
positioning a reinforcement material between the first component and the second component; and
curing the reinforcement material.

17. A computer device, comprising:
a printed circuit board (PCB);
a component coupled to the PCB; and
a plurality of adhesive elements located between the PCB and the component, wherein the plurality of adhesive elements couple the component to the PCB.

18. The computer device of claim 17, wherein each adhesive element of the plurality of adhesive elements is equidistance from adjacent adhesive elements of the plurality of adhesive elements.

19. The computer device of claim 17, wherein the plurality of adhesive elements extend for an entirety of a surface of the component, wherein the surface is located adjacent to the PCB.

20. The computer device of claim 17, wherein the plurality of adhesive elements include carbon, hydrogen, nitrogen, oxygen, or silicon.
